(19) United States
(12) Patent Application Publication
(10) Pub. No.: US 2025/0113473 A1
(43) Pub. Date: Apr. 3, 2025

(54) Electrostatic Shield For Electronic Device

(71) Applicant: APPLE INC., Cupertino, CA (US)

(72) Inventors: Shaowu Huang, Los Altos, CA (US); Jan K. Quijalvo, San Jose, CA (US); Jing Li Lim, Sunnyvale, CA (US); Keong W. Kam, San Jose, CA (US); Martin R. Kardasz, Mountain View, CA (US); Michael J. Woods, Sunnyvale, CA (US); Ramachandran Chundru, Cupertino, CA (US)

(21) Appl. No.: 18/806,217

(22) Filed: Aug. 15, 2024

Related U.S. Application Data
(60) Provisional application No. 63/540,952, filed on Sep. 28, 2023.

(51) Int. Cl. H05K 9/00; G06F 1/16

(52) U.S. Cl. CPC H05K 9/0054; G06F 1/163; H05K 9/0079

(57) ABSTRACT

A head-mounted device includes a frame and an optical module movably coupled to the frame. The optical module includes a display configured to show content to a user wearing the head-mounted device and an optical module control board electrically coupled to the display. The optical module control board is configured to provide the content to the display. A shield is coupled to the optical module control board and is configured to dissipate an electrical charge.

### CROSS-REFERENCE TO RELATED APPLICATIONS

This application claims priority to U.S. Provisional Application Ser. No. 63/540,952, filed Sep. 28, 2023, the contents of which are incorporated herein by reference.

### FIELD

The present disclosure relates generally to the field of protecting an electronic device from the effects of electrostatic discharge and electrostatic coupling.

### BACKGROUND

A head-mounted device may include various electronic components configured for operation of the head-mounted device and configured to display content. Operation of the electronic components may be negatively affected if exposed to an electrostatic discharge or electrostatic coupling.

### SUMMARY

One aspect of the disclosure is a head-mounted device that includes a frame and an optical module movably coupled to the frame. The optical module includes a display configured to show content to a user wearing the head-mounted device and an optical module control board electrically coupled to the display. The optical module control board is configured to provide the content to the display. A shield is coupled to the optical module control board and is configured to dissipate an electrical charge.

Another aspect of the disclosure is an optical module for use in a head-mounted device. The optical module includes a display and an optical module control board configured to provide a signal to the display. The optical module control board includes a first surface having electrical pins and a second surface located opposite the first surface, the display being configured to show content based on the signal. The optical module control board also includes a flexible electrical connector electrically coupled to the display and to the optical module control board, and it is configured to provide the signal to the display via the flexible electrical connector. A first shield portion is coupled to the first surface and the second surface of the optical module control board and is configured to dissipate an electrical charge. A second shield portion is coupled to the flexible electrical connector and is configured to dissipate the electrical charge.

Another aspect of the disclosure is a head-mounted device that includes a frame, a stage movably coupled to the frame, and an optical module coupled to the stage and configured to move laterally relative to the frame. The optical module includes a display configured to show content and an optical module control board electrically coupled to the display. The optical module also includes a main control board electrically coupled to the optical module control board by an electrical connector, and the main control board is configured to provide a first signal to the optical module control board. The optical module control board is configured to provide a second signal to the display based on the first signal, and the display is configured to show the content based on the second signal. A shield is coupled to the optical module control board and is configured to dissipate an electrical charge. An additional shield surrounds the electrical connector and is configured to dissipate the electrical charge.

### BRIEF DESCRIPTION OF THE DRAWINGS

FIG. 1 is an illustration of a head-mounted device.

FIG. 2 is an illustration of an optical module of the head-mounted device of FIG. 1.

FIGS. 3A and 3B are illustrations of an optical module control board and a flexible electrical connector of the optical module of FIG. 2.

### DETAILED DESCRIPTION

The disclosure herein relates to a head-mounted device. The head-mounted device may include an optical module that has a display for showing content to a user. The optical module may also have an optical module control board that may be electrically coupled to the optical module and configured to provide the content to the display. The head-mounted device may be susceptible to the effects of release of an electrostatic charge that accumulates on components of the head-mounted device, such as an electrostatic discharge or electrostatic coupling. More specifically, operation of the head-mounted device may be affected when the electronic components within the head-mounted device (e.g., the optical module control board, the electrical connectors, etc.) are exposed to the electrostatic discharge or the electrostatic coupling. Implementations described herein are directed to a shield that is configured to dissipate and/or redirect an electrical charge (e.g., an electrostatic discharge or an electrostatic coupling) in proximity to the head-mounted device. In some implementations, the shield is coupled to the optical module control board. The shield may include a first shield portion coupled to the optical module control board and a second shield portion coupled to a flexible electrical connector. In some implementations, the shield may include a first shield portion coupled to the optical module control board and a second shield portion that surrounds an electrical connector that is coupled to a main control board.

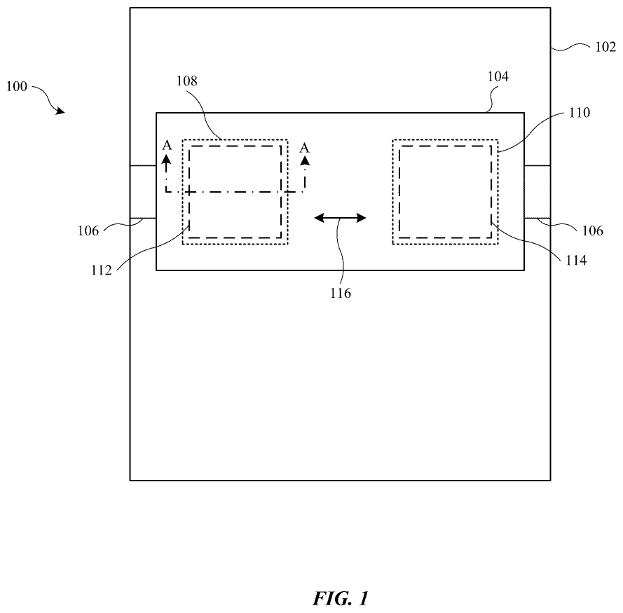

FIG. 1 is an illustration of a head-mounted device 100 worn by a user 102. The head- mounted device 100 is a computer-generated reality device that is configured to display computer-generated reality content to the user 102 using a near-eye display, and optionally, according to tracked motion of the head-mounted device 100 in order to display computer- generated reality content to the user 102 in a manner that simulates viewing of the content based on a position and an orientation of a head of the user 102. As one example, the head-mounted device 100 may be configured as a virtual reality device in which the head-mounted device 100 blocks images from the environment from reaching the user 102 and instead presents the user 102 with virtual images presented on a display near the eyes of the user 102. As another example, the head-mounted device 100 may be configured as a video passthrough augmented reality device in which the head-mounted device 100 obtains images of the environment around the head-mounted device 100 (e.g., using one or more cameras), superimposes virtual images on top of the images from the environment in order to define combined images, and displays the combined images to the user via one or more displays (e.g., including one or more display screens and lenses). Other configurations may be used for the head-mounted device 100.

The head-mounted device 100 includes a frame 104 that is configured to provide structural support for components of the head-mounted device 100 that are coupled directly or indirectly to the frame 104. The frame 104 may be formed from any type of material of sufficient strength to support the components of the head-mounted device 100. For example, the frame 104 may be formed from metal (e.g., aluminum, zinc, nickel, brass, steel, etc., or a combination thereof). The frame 104 may also be formed from plastic (e.g., polycarbonate, polypropylene, nylon, etc., or a combination thereof). In some implementations, the frame 104 is a multi-part assembly, and the parts thereof may be formed from the same material or from different materials.

The head-mounted device 100 may include a headband 106 configured to secure the head-mounted device 100 to the head of the user 102. As shown, the headband 106 is coupled to the frame 104 and may extend around a back of the head of the user 102. The headband 106 may be formed from any material capable of securing the head-mounted device 100 to the head of the user 102. For example, the headband 106 may be formed from an elastic textile material configured to stretch to accommodate the head of the user 102 and to contract around the head of the user 102 to secure the head-mounted device 100 to the head of the user 102.

The head-mounted device 100 may also include a first optical module 108 and a second optical module 110. The first optical module 108 is configured to show content to a first eye of the user 102 via a first display 112 (shown in dashed line as hidden). The second optical module 110 is configured to show the content to a second eye of the user 102 via a second display 114 (shown in dashed line a hidden). In some implementations, the first optical module 108 and the second optical module 110 are movably coupled to the frame 104. For example, the first optical module 108 and the second optical module 110 may be movable in a lateral direction (e.g., in the direction of the arrow 116) relative to the frame 104. The first optical module 108 and the second optical module 110 may also be movable in the lateral direction relative to each other. Allowing lateral movement between the first optical module 108 and the second optical module 110 allows the user 102 to adjust a distance between the first optical module 108 and the second optical module 110 to accommodate an interpupillary distance between the eyes of the user 102.

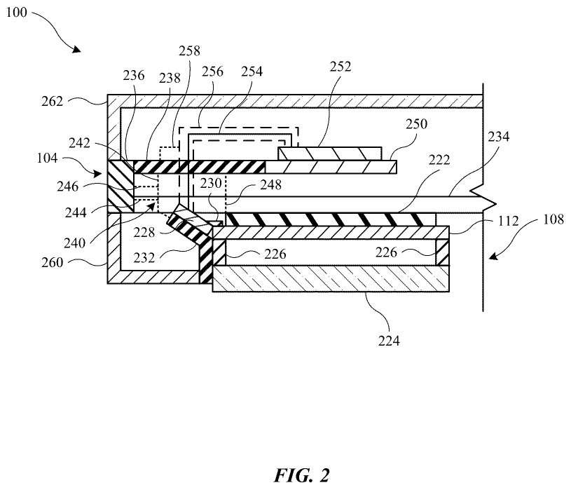

FIG. 2 is an illustration of a cross-section of the first optical module 108 of the head-mounted device 100 of FIG. 1 taken across line A-A of FIG. 1. Though the description below is made with reference to the first optical module 108, it also applies to the second optical module 110.

The first optical module 108 is shown to include the first display 112. The first display 112 is a light-emitted display component, such as a display screen, that is configured to show content to the user 102 that is wearing the head-mounted device 100. In some implementations, the first display 112 may be a liquid crystal display. The first display 112 may also be an organic light emitting diode (OLED) display. In some implementations, the first display 112 may be a digital light projector (DLP) microdisplay. The first display 112 may also be a liquid crystal on silicon (LCoS) microdisplay. The above are example implementations of the first display 112, and other systems or devices for displaying content to the user 102 may also be implemented.

The first optical module 108 also includes a heat sink 222 coupled to the first display 112. The heat sink 222 is configured to absorb and/or dissipate heat generated by the first display 112 to limit overheating of the first display 112. In some implementations, the heat sink 222 may be formed from a thermally conductive material such that heat generated by the first display 112 is transferred to the heat sink 222 (e.g., by conduction) to maintain an operating temperature of the first display 112. For example, the heat sink 222 may be formed from aluminum or aluminum alloys, copper or copper alloys, graphite, thermally conductive plastics, or a combination thereof. The heat sink 222 may also have a shape suitable for heat transfer. For example, the heat sink 222 may be a solid block of material that is in contact with the first display 112. The heat sink 222 may also include protrusions (e.g., fins) that extend from a main body of the heat sink 222 to facilitate heat transfer. In some implementations, the heat sink 222 may include one or more channels through which liquid flows to facilitate heat transfer from the first display 112. The heat sink 222 may also include a fan or other air moving structure to facilitate heat transfer from the first display 112.

The first optical module 108 also includes a lens 224. The lens 224 is configured to direct the content from the first display 112 to an eye of the user 102 to allow the user 102 to view the content.

The lens 224 may be coupled to the first display 112 by a bezel 226. The bezel 226 is configured to support the lens 224 relative to the first display 112 and to limit motion of the lens 224 relative to the first display 112. In the illustrated implementation, the bezel 226 is a generally tubular structure, with the first display 112 positioned at a first end thereof and with the lens 224 positioned at a second end thereof. Thus, the first display 112 and the lens 224 may be spaced along a longitudinal axis of the tubular structure of the bezel 226, and light emitted by the first display 112 may travel generally along the longitudinal axis of the tubular structure of the bezel from the first display 112 to the lens 224, where the light passes through the lens 224 and outward toward the eyes of the user 102. The bezel 226 may be formed from any material suitable to support the lens 224 relative to the first display 112 (e.g., the bezel 226 may be formed from metal, plastic, composite materials, etc.).

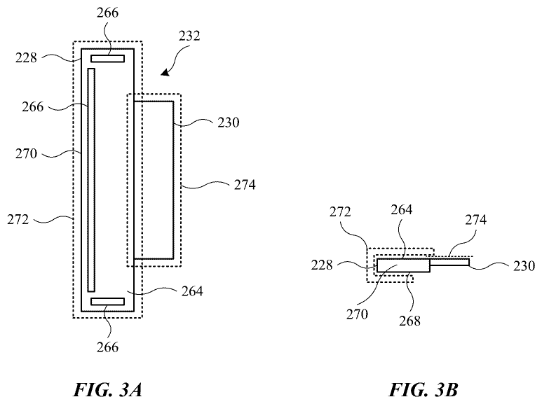

The first optical module 108 also includes an optical module control board 228. The optical module control board 228 is electrically coupled to the first display 112 and is configured to provide a signal to the first display 112 (e.g., to provide the content to the first display 112). More specifically, the first display 112 is configured to show the content based on the signal received from the optical module control board 228. In some implementations, the optical module control board 228 may include one or more integrated circuits, memory components, and associated support circuitry. The optical module control board 228 may also include various electrical connectors and/or interfaces to facilitate electrical connection with other components and/or systems of the head-mounted device 100. The optical module control board 228 is further described with reference to FIGS. 3A-B.

The first optical module 108 also includes a flexible electrical connector 230 configured to be electrically coupled to the first display 112 and to the optical module control board 228. The flexible electrical connector 230 allows the optical module control board 228 to provide a signal to the first display 112. For example, the optical module control board 228 is configured to provide the signal for the content to the first display 112 via the flexible electrical connector 230. In some implementations, the flexible electrical connector 230 may be a flexible flat cable, a flexible printed circuit, a flexible ribbon cable, or any other type of electrical connector suitable to facilitate a flexible connection between the optical module control board 228 and the first display 112.

A shield 232 may be coupled to the optical module control board 228. The shield 232 is configured to dissipate and/or redirect an electrical charge that would otherwise be directed to the optical module control board 228 and/or the flexible electrical connector 230. The shield 232 may also be configured to limit a buildup of an electrical charge that may lead to an electrostatic discharge or an electrostatic coupling. Thus, the shield 232 may be formed from an electrically conductive material. In some implementations, the shield 232 may be formed from metal (e.g., aluminum, zinc, nickel, brass, steel, etc., or a combination thereof). The shield 232 is further described with reference to FIGS. 3A-B.

The electrical charge may be in the form of electrostatic discharge or electrostatic coupling from an electrically charged object in proximity to the head-mounted device 100. In some implementations, the charged object may be another electronic device. The charged object may also be a non-electronic device that has accumulated static electricity. For example, the charged object may be the user 102 (e.g., the user 102 may accumulate an electrical charge by, for example, walking across a carpeted floor, and the accumulated electrical charge may flow to the head-mounted device 100 when the user 102 attempts to touch the head-mounted device 100). The charged object may also be another user that is not wearing the head-mounted device 100. The electrical charge may also be in the form of electrostatic coupling between the head-mounted device 100 and an electrically charged object in proximity to the head-mounted device 100. For example, electrical energy from an electric field associated with the optical module control board 228 and/or the flexible electrical connector 230 may couple with electrical energy from an electric field associated with the electrically charged object, thereby increasing the electrical energy in the optical module control board 228 and/or the flexible electrical connector 230. Increasing the electrical energy in the optical module control board 228 and/or the electrical connector 230 may limit performance of the optical module control board 228 and/or the flexible electrical connector 230.

The head-mounted device 100 also includes a stage 234 configured to facilitate lateral movement of the first optical module 108 relative to the frame 104 of the head-mounted device 100. The first optical module 108 is coupled to the stage 234. For example, the heat sink 222 may be coupled to the stage 234, as shown in FIG. 2. In some implementations, other portions of the first optical module 108 may be coupled to the stage 234. In an example implementation, the first optical module 108 is fixed to the stage 234 and the stage 234 is movably coupled to the frame 104. For example, the stage 234 may be coupled to an actuator (e.g., an electric linear actuator) configured to move the stage 234 laterally relative to the frame 104. Thus, the first optical module 108 may be configured to move laterally relative to the frame 104 based on lateral movement of the stage 234 relative to the frame 104. The first optical module 108 may also be movably coupled to the stage 234, and the stage 234 may be fixed to the frame 104. For example, the stage 234 may include an actuator (e.g., an electric linear actuator) configured to move the first optical module 108 relative to the stage 234. Accordingly, the optical module control board 228 may be configured to move laterally relative to the frame 104 based on lateral movement of the first optical module 108 relative to the stage 234.

The frame 104 is shown to include an outer chassis 236. The outer chassis 236 is configured to extend around a perimeter of the head-mounted device 100 to provide structural support for components of the head-mounted device 100. The outer chassis 236 may also provide a grounding surface for the electrical charge dissipated and/or redirected by the shield 232. For example, the outer chassis 236 may be formed from an electrically conductive material such as aluminum, zinc, nickel, brass, steel, or a combination thereof. The frame 104 may also include an inner chassis 238 located within the head-mounted device 100 and configured to provide structural support for components of the head-mounted device 100 that may not be coupled to the outer chassis 236. In some implementations, the inner chassis 238 is coupled to the outer chassis 236, and the outer chassis 236 is configured to provide structural support for the inner chassis 238. Similar to the outer chassis 236, the inner chassis 238 may provide a grounding surface for the electrical charge dissipated and/or redirected by the shield 232. Accordingly, the inner chassis 238 may be formed from materials similar to those used to form the outer chassis 236.

A first grounding component 240 is shown coupled to and extending between the shield 232 and the frame 104 (in dotted line). The first grounding component 240 is configured to direct an electrical charge (e.g., from an electrostatic discharge or electrostatic coupling, etc.) to the frame 104 and away from the optical module control board 228 and other electrical components of the head-mounted device 100. In some implementations, the first grounding component 240 includes a first ground wire 242 that is coupled to and extends between the shield 232 and the inner chassis 238. The first grounding component 240 may also include a second ground wire 244 that is coupled to and extends between the shield 232 and the outer chassis 236. The first grounding component 240 may also include a third ground wire 246 that is coupled to and extends between the shield 232 and the outer chassis 236. More or fewer ground wires may be implemented and coupled to one or both of the outer chassis 236 and the inner chassis 238 in various implementations.

A second grounding component 248 may be coupled to and extend between the heat sink 222 and the inner chassis 238. The second grounding component 248 is configured to direct an electrical charge (e.g., from an electrostatic discharge or electrostatic coupling, etc.) to the frame 104 and away from the optical module control board 228 and other electrical components of the head-mounted device 100. In some implementations, the second grounding component 248 may be or include a single ground wire extending between the heat sink 222 and the inner chassis 238. The second grounding component 248 may also include more than one ground wire that extends between the heat sink 222 and the inner chassis 238 and/or between the heat sink 222 and the outer chassis 236.

The head-mounted device 100 also includes a fan 250 coupled to the inner chassis 238. The fan 250 is configured to direct air toward the optical module control board 228 to reduce a temperature of the optical module control board 228. More specifically, the fan 250 is configured to cool the heat sink 222 and/or the first display 112 by directing air over the heat sink 222 and/or the first display 112 to facilitate heat transfer via convection (e.g., airflow over a surface).

A main control board 252 is coupled to the fan 250 and is electrically coupled to the optical module control board 228 by an electrical connector 254. The main control board 252 is configured to control operation of the head-mounted device 100. In some implementations, the main control board 252 controls operation of the optical module control board 228. For example, the main control board 252 may be configured to provide a first signal (e.g., a control signal related to the content to be shown on the first display 112) to the optical module control board 228. In response, the optical module control board 228 may be configured to provide a second signal (e.g., a signal that includes the content to be shown) to the first display 112. The first display 112 may be configured to show the content based on the second signal.

As an example, the functionality of the main control board 252 may include rendering the content that will be output by the first display 112, and thereby defining a video stream comprising images as the first signal. The video stream included in the first signal is then provided to and interpreted by the optical module control board 228. The optical module control board 228 may convert the images included in the first signal into a format that can be used to control selective illumination of the display elements (e.g., pixels) of the first display 112, and this is output by the optical module control board 228 to the first display 112 as the second signal. Similar to the optical module control board 228, the main control board 252 may include one or more integrated circuits, memory components, and associated support circuitry. The optical module control board 228 may also include various electrical connectors and/or interfaces to facilitate electrical connection with the main control board 252 and other components and/or systems of the head-mounted device 100.

An additional shield 256 extends between the main control board 252 and the optical module control board 228 and surrounds the electrical connector 254. The additional shield 256 may be formed from an electrically conductive material (e.g., the additional shield 256 may be formed from metal) and may be configured to dissipate and/or redirect an electrical charge that would otherwise be directed to the electrical connector 254. To dissipate and/or redirect the electrical charge, a third grounding component 258 may be coupled to and extend between the additional shield 256 and the inner chassis 238. In some implementations, the third grounding component 258 may also be coupled to and extend between the additional shield 256 and the outer chassis 236.

The head-mounted device 100 is also shown to include an inner cover 260 that is coupled to the frame 104 and is configured to extend around the optical module control board 228. The inner cover 260 is configured to enclose the internal components of the head-mounted device 100 to limit viewing of the internal components. The head-mounted device 100 also includes an outer cover 262 that is coupled to the frame 104 and is located opposite the inner cover 260 with respect to the frame 104. The outer cover 262 is also configured to enclose the internal components of the head-mounted device 100 to limit viewing of the internal components.

FIGS. 3A-3B are illustrations of the optical module control board 228 and the flexible electrical connector 230 of the first optical module 108 of FIG. 2. FIG. 3A shows a top view of the optical module control board 228 and the flexible electrical connector 230. FIG. 3B shows a side view of the optical module control board 228 and the flexible electrical connector 230.

The optical module control board 228 is shown to include a first surface 264 having electrical pins 266 located around a portion of a perimeter of the first surface 264. The electrical pins 266 are electrically coupled to the optical module control board 228 and are configured to conduct a current through the optical module control board 228. As an example, the electrical pins 266 may serve as input pins or output pins for circuits that are located on the optical module control board 228. As shown in FIG. 3B, a second surface 268 of the optical module control board 228 is positioned opposite the first surface 264 and an edge surface 270 is located between the first surface 264 and the second surface 268.

The shield 232 is configured to cover the electrical pins 266 to direct an electrical charge away from the electrical pins 266 and away from the optical module control board 228. As an example, the shield 232 may be physically coupled to the optical module control board 228 such that at least a portion of the shield 232 is spaced from the first surface 264, and such that the electrical pins 266 are located between the first surface 264 and the shield 232. Directing the electrical charge away from the electrical pins 266 and away from the optical module control board 228 may limit disruption of the performance of the optical module control board 228 (and thus, the head-mounted device 100) by the electrical charge.

The shield 232 may be configured to cover a portion of the first surface 264 (e.g., the portion of the first surface 264 that includes the electrical pins 266), a portion of the second surface 268, and a portion of the edge surface 270. Covering portions of the second surface 268 and the edge surface 270 provides additional protection for the optical module control board 228 from electrical charge. For example, if a portion of the second surface 268 and/or the edge surface 270 were not covered by the shield 232, the electrical charge may accumulate on the second surface 268 and/or the edge surface 270 of the optical module control board 228. The electrical charge may be strong enough to affect operation of the optical module control board 228 even without a discharge of the electrical charge, for example, to the electrical pins 266 on the first surface 264.

As shown, the shield 232 may have multiple portions. For example, the shield 232 may have a first shield portion 272 and a second shield portion 274 (shown in dotted line). The first shield portion 272 is configured to dissipate and/or redirect an electrical charge directed toward the optical module control board 228. In some implementations, the first shield portion 272 is coupled to the first surface 264. The first shield portion 272 may also be coupled to the second surface 268. The first shield portion 272 may also be coupled to the edge surface 270. The first shield portion 272 may be configured to cover a portion of the first surface 264 (e.g., the first shield portion 272 may be configured to cover the electrical pins 266), a portion of the second surface 268, and a portion of the edge surface 270. The first shield portion 272 may be formed from an electrically conductive material to facilitate dissipation and/or redirection of the electrical charge. In some implementations, the first shield portion 272 is formed from metal.

In some implementations, the second shield portion 274 is coupled to the flexible electrical connector 230 and is configured to dissipate and/or redirect electrical charge directed toward the flexible electrical connector 230. The second shield portion 274 may be flexible to match a shape or contour of the flexible electrical connector 230. Thus, the second shield portion 274 may be formed from a material that allows for flexibility. In some implementations, the second shield portion 274 is formed from metal (e.g., a thin-walled metal that allows for flexibility). The second shield portion 274 may also be formed from a plastic material (e.g., polycarbonate, polypropylene, nylon, etc., or a combination thereof). In some implementations, the plastic material may include an adhesive portion that is configured to couple with the flexible electrical connector 230 (e.g., the second shield portion 274 may be in the form of shield tape). The plastic material conducts electricity poorly and therefore limits an electrical charge from accumulating on the electrical components. The plastic material may also limit accumulation of an electrical charge that may lead to an electrostatic discharge or electrostatic coupling. Thus, instead of directing an electrical charge away from the optical module control board 228 (like a shield portion formed from metal, such as the first shield portion 272), a shield formed from plastic may limit propagation of the electrical charge and/or may limit electrostatic coupling.

As shown in FIGS. 3A and 3B, the first shield portion 272 and the second shield portion 274 may overlap. For example, a portion of the first shield portion 272 may extend over the flexible electrical connector 230, and a portion of the second shield portion 274 may extend over the optical module control board 228. In some implementations, the first shield portion 272 and the second shield portion 274 may not overlap. For example, the first shield portion 272 and the second shield portion 274 may abut each other at an interface between the optical module control board 228 and the flexible electrical connector 230.

As described with reference to FIG. 2, the shield 232 may be coupled to the first grounding component 240. For example, the first grounding component 240 may extend between the first shield portion 272 and the frame 104. The first grounding component 240 may also extend between the second shield portion 274 and the frame 104. In some implementations, the first shield portion 272 and the second shield portion 274 may each have a separate grounding component, equivalent to the first grounding component 240, that extends between a respective one of the first shield portion 272 or the second shield portion 274 and the frame 104.

A physical environment refers to a physical world that people can sense and/or interact with without aid of electronic systems. Physical environments, such as a physical park, include physical articles, such as physical trees, physical buildings, and physical people. People can directly sense and/or interact with the physical environment, such as through sight, touch, hearing, taste, and smell.

In contrast, a computer-generated reality (CGR) environment refers to a wholly or partially simulated environment that people sense and/or interact with via an electronic system. In CGR, a subset of a person's physical motions, or representations thereof, are tracked, and, in response, one or more characteristics of one or more virtual objects simulated in the CGR environment are adjusted in a manner that comports with at least one law of physics. For example, a CGR system may detect a person's head turning and, in response, adjust graphical content and an acoustic field presented to the person in a manner similar to how such views and sounds would change in a physical environment. In some situations (e.g., for accessibility reasons), adjustments to characteristic(s) of virtual object(s) in a CGR environment may be made in response to representations of physical motions (e.g., vocal commands).

A person may sense and/or interact with a CGR object using any one of their senses, including sight, sound, touch, taste, and smell. For example, a person may sense and/or interact with audio objects that create three-dimensional or spatial audio environment that provides the perception of point audio sources in three-dimensional space. In another example, audio objects may enable audio transparency, which selectively incorporates ambient sounds from the physical environment with or without computer-generated audio. In some CGR environments, a person may sense and/or interact only with audio objects.

Examples of CGR include virtual reality and mixed reality.

A virtual reality (VR) environment refers to a simulated environment that is designed to be based entirely on computer-generated sensory inputs for one or more senses. A VR environment comprises a plurality of virtual objects with which a person may sense and/or interact. For example, computer-generated imagery of trees, buildings, and avatars representing people are examples of virtual objects. A person may sense and/or interact with virtual objects in the VR environment through a simulation of the person's presence within the computer- generated environment, and/or through a simulation of a subset of the person's physical movements within the computer-generated environment.

In contrast to a VR environment, which is designed to be based entirely on computer-generated sensory inputs, a mixed reality (MR) environment refers to a simulated environment that is designed to incorporate sensory inputs from the physical environment, or a representation thereof, in addition to including computer-generated sensory inputs (e.g., virtual objects). On a virtuality continuum, a mixed reality environment is anywhere between, but not including, a wholly physical environment at one end and virtual reality environment at the other end.

In some MR environments, computer-generated sensory inputs may respond to changes in sensory inputs from the physical environment. Also, some electronic systems for presenting an MR environment may track location and/or orientation with respect to the physical environment to enable virtual objects to interact with real objects (that is, physical articles from the physical environment or representations thereof). For example, a system may account for movements so that a virtual tree appears stationary with respect to the physical ground.

Examples of mixed realities include augmented reality and augmented virtuality.

An augmented reality (AR) environment refers to a simulated environment in which one or more virtual objects are superimposed over a physical environment, or a representation thereof. For example, an electronic system for presenting an AR environment may have a transparent or translucent display through which a person may directly view the physical environment. The system may be configured to present virtual objects on the transparent or translucent display, so that a person, using the system, perceives the virtual objects superimposed over the physical environment. Alternatively, a system may have an opaque display and one or more imaging sensors that capture images or video of the physical environment, which are representations of the physical environment. The system composites the images or video with virtual objects and presents the composition on the opaque display. A person, using the system, indirectly views the physical environment by way of the images or video of the physical environment, and perceives the virtual objects superimposed over the physical environment. As used herein, a video of the physical environment shown on an opaque display is called “pass-through video,” meaning a system uses one or more image sensor(s) to capture images of the physical environment and uses those images in presenting the AR environment on the opaque display. Further alternatively, a system may have a projection system that projects virtual objects into the physical environment, for example, as a hologram or on a physical surface, so that a person, using the system, perceives the virtual objects superimposed over the physical environment.

An augmented reality environment also refers to a simulated environment in which a representation of a physical environment is transformed by computer-generated sensory information. For example, in providing pass-through video, a system may transform one or more sensor images to impose a select perspective (e.g., viewpoint) different than the perspective captured by the imaging sensors. As another example, a representation of a physical environment may be transformed by graphically modifying (e.g., enlarging) portions thereof, such that the modified portion may be representative but not photorealistic versions of the originally captured images. As a further example, a representation of a physical environment may be transformed by graphically eliminating or obfuscating portions thereof.

An augmented virtuality (AV) environment refers to a simulated environment in which a virtual or computer-generated environment incorporates one or more sensory inputs from the physical environment. The sensory inputs may be representations of one or more characteristics of the physical environment. For example, an AV park may have virtual trees and virtual buildings, but people with faces photorealistically reproduced from images taken of physical people. As another example, a virtual object may adopt a shape or color of a physical article imaged by one or more imaging sensors. As a further example, a virtual object may adopt shadows consistent with the position of the sun in the physical environment.

There are many different types of electronic systems that enable a person to sense and/or interact with various CGR environments. Examples include head-mounted systems, projection-based systems, heads-up displays (HUDs), vehicle windshields having integrated display capability, windows having integrated display capability, displays formed as lenses designed to be placed on a person's eyes (e.g., similar to contact lenses), headphones/earphones, speaker arrays, input systems (e.g., wearable or handheld controllers with or without haptic feedback), smartphones, tablets, and desktop/laptop computers. A head-mounted system may have one or more speaker(s) and an integrated opaque display. Alternatively, a head-mounted system may be configured to accept an external opaque display (e.g., a smartphone). The head-mounted system may incorporate one or more imaging sensors to capture images or video of the physical environment, and/or one or more microphones to capture audio of the physical environment. Rather than an opaque display, a head-mounted system may have a transparent or translucent display. The transparent or translucent display may have a medium through which light representative of images is directed to a person's eyes. The display may utilize digital light projection, OLEDs, LEDs, uLEDs, liquid crystal on silicon, laser scanning light source, or any combination of these technologies. The medium may be an optical waveguide, a hologram medium, an optical combiner, an optical reflector, or any combination thereof. In one embodiment, the transparent or translucent display may be configured to become opaque selectively. Projection-based systems may employ retinal projection technology that projects graphical images onto a person's retina. Projection systems also may be configured to project virtual objects into the physical environment, for example, as a hologram or on a physical surface.

As described above, one aspect of the present technology is the gathering and use of data available from various sources for use during operation of a head-mounted device. As an example, such data may identify the user and include user-specific settings or preferences. The present disclosure contemplates that in some instances, this gathered data may include personal information data that uniquely identifies or can be used to contact or locate a specific person. Such personal information data can include demographic data, location-based data, telephone numbers, email addresses, twitter ID's, home addresses, data or records relating to a user's health or level of fitness (e.g., vital signs measurements, medication information, exercise information), date of birth, or any other identifying or personal information.

The present disclosure recognizes that the use of such personal information data, in the present technology, can be used to the benefit of users. For example, a user profile may be established that stores user related information that allows adjustment of one or more optical modules of the head-mounted device according to user preferences]. Accordingly, use of such personal information data enhances the user's experience.

The present disclosure contemplates that the entities responsible for the collection, analysis, disclosure, transfer, storage, or other use of such personal information data will comply with well-established privacy policies and/or privacy practices. In particular, such entities should implement and consistently use privacy policies and practices that are generally recognized as meeting or exceeding industry or governmental requirements for maintaining personal information data private and secure. Such policies should be easily accessible by users, and should be updated as the collection and/or use of data changes. Personal information from users should be collected for legitimate and reasonable uses of the entity and not shared or sold outside of those legitimate uses. Further, such collection/sharing should occur after receiving the informed consent of the users. Additionally, such entities should consider taking any needed steps for safeguarding and securing access to such personal information data and ensuring that others with access to the personal information data adhere to their privacy policies and procedures. Further, such entities can subject themselves to evaluation by third parties to certify their adherence to widely accepted privacy policies and practices. In addition, policies and practices should be adapted for the particular types of personal information data being collected and/or accessed and adapted to applicable laws and standards, including jurisdiction-specific considerations. For instance, in the US, collection of or access to certain health data may be governed by federal and/or state laws, such as the Health Insurance Portability and Accountability Act (HIPAA); whereas health data in other countries may be subject to other regulations and policies and should be handled accordingly. Hence different privacy practices should be maintained for different personal data types in each country.

Despite the foregoing, the present disclosure also contemplates embodiments in which users selectively block the use of, or access to, personal information data. That is, the present disclosure contemplates that hardware and/or software elements can be provided to prevent or block access to such personal information data. For example, in the case of storing a user profile for adjustment of an optical module, the present technology can be configured to allow users to select to “opt in” or “opt out” of participation in the collection of personal information data during registration for services or anytime thereafter. In another example, users can select not to provide data regarding usage of specific applications. In yet another example, users can select to limit the length of time that application usage data is maintained or entirely prohibit the development of an application usage profile. In addition to providing “opt in” and “opt out” options, the present disclosure contemplates providing notifications relating to the access or use of personal information. For instance, a user may be notified upon downloading an app that their personal information data will be accessed and then reminded again just before personal information data is accessed by the app.

Moreover, it is the intent of the present disclosure that personal information data should be managed and handled in a way to minimize risks of unintentional or unauthorized access or use. Risk can be minimized by limiting the collection of data and deleting data once it is no longer needed. In addition, and when applicable, including in certain health related applications, data de-identification can be used to protect a user's privacy. De-identification may be facilitated, when appropriate, by removing specific identifiers (e.g., date of birth, etc.), controlling the amount or specificity of data stored (e.g., collecting location data at a city level rather than at an address level), controlling how data is stored (e.g., aggregating data across users), and/or other methods.

Therefore, although the present disclosure broadly covers use of personal information data to implement one or more various disclosed embodiments, the present disclosure also contemplates that the various embodiments can also be implemented without the need for accessing such personal information data. That is, the various embodiments of the present technology are not rendered inoperable due to the lack of all or a portion of such personal information data. For example, user information may be determined each time the head-mounted device is used, such as by obtaining the user information in real time, and without subsequently storing the information or associating with the particular user.

What is claimed is:

1. A head-mounted device, comprising:
a frame;
an optical module movably coupled to the frame, the optical module comprising:
a display configured to show content to a user wearing the head-mounted device;
and
an optical module control board electrically coupled to the display and configured to provide the content to the display; and
a shield coupled to the optical module control board and configured to dissipate an electrical charge.

2. The head-mounted device of claim 1, wherein the shield is formed from metal.

3. The head-mounted device of claim 1, wherein the optical module control board has electrical pins, and wherein the shield is configured to cover the electrical pins to direct the electrical charge away from the electrical pins.

4. The head-mounted device of claim 1, further comprising a grounding component coupled to and extending between the shield and the frame, the grounding component configured to direct the electrical charge from the shield to the frame.

5. The head-mounted device of claim 4, wherein the grounding component includes a first ground wire and a second ground wire, wherein the first ground wire is coupled to and extends between the shield and an inner chassis of the frame, and wherein the second ground wire is coupled to and extends between the first ground wire and an outer chassis of the frame.

6. The head-mounted device of claim 1, wherein the optical module control board includes a first surface, a second surface located opposite the first surface, and an edge surface located between the first surface and the second surface, and wherein the shield is configured to cover a portion of the first surface, a portion of the second surface, and a portion of the edge surface.

7. An optical module for use in a head-mounted device, comprising:
a display;
an optical module control board configured to provide a signal to the display and including a first surface having electrical pins and a second surface located opposite the first surface, wherein the display is configured to show content based on the signal;
a flexible electrical connector electrically coupled to the display and to the optical module control board, wherein the optical module control board is configured to provide the signal to the display via the flexible electrical connector;
a first shield portion coupled to the first surface and the second surface of the optical module control board and configured to dissipate an electrical charge; and
a second shield portion coupled to the flexible electrical connector and configured to dissipate the electrical charge.

8. The optical module of claim 7, wherein the first shield portion is formed from metal and the second shield portion is flexible and includes plastic.

9. The optical module of claim 7, wherein the first shield portion is configured to cover the electrical pins.

10. The optical module of claim 7, wherein the optical module control board includes an edge surface extending between the first surface and the second surface, and wherein the first shield portion is configured to cover the edge surface.

11. The optical module of claim 7, further comprising a first grounding component coupled to and extending between the first shield portion and a frame of the head-mounted device, the first grounding component configured to direct the electrical charge to the frame.

12. The optical module of claim 11, further comprising a second grounding component coupled to and extending between a heat sink and the frame, the second grounding component configured to direct the electrical charge to the frame.

13. The optical module of claim 11, wherein the first grounding component includes a first ground wire and a second ground wire, wherein the first ground wire is coupled to and extends between the first shield portion and an inner chassis of the head-mounted device, and wherein the second ground wire is coupled to and extends between the first ground wire and an outer chassis of the head-mounted device.

14. The optical module of claim 13, further comprising a third ground wire coupled to and extending between the first ground wire and the outer chassis of the head-mounted device.

15. A head-mounted device, comprising:
a frame;
a stage movably coupled to the frame;
an optical module coupled to the stage and configured to move laterally relative to the frame, the optical module comprising:
a display configured to show content, and
an optical module control board electrically coupled to the display;
a main control board electrically coupled to the optical module control board by an electrical connector, the main control board configured to provide a first signal to the optical module control board, the optical module control board configured to provide a second signal to the display based on the first signal, and the display configured to show the content based on the second signal;
a shield coupled to the optical module control board and configured to dissipate an electrical charge; and
an additional shield surrounding the electrical connector and configured to dissipate the electrical charge.

16. The head-mounted device of claim 15, wherein the shield and the additional shield are formed from metal.

17. The head-mounted device of claim 15, wherein the optical module control board has electrical pins, and wherein the shield is configured to cover the electrical pins to direct the electrical charge away from the electrical pins.

18. The head-mounted device of claim 15, wherein the optical module control board includes a first surface, a second surface located opposite the first surface, and an edge surface located between the first surface and the second surface, and wherein the shield is configured to cover a portion of the first surface, a portion of the second surface, and a portion of the edge surface.

19. The head-mounted device of claim 18, further comprising a grounding component coupled to and extending between the shield and the frame, the grounding component configured to direct the electrical charge to the frame.

20. The head-mounted device of claim 19, wherein the grounding component includes a first ground wire and a second ground wire, wherein the first ground wire is coupled to and extends between the shield and an inner chassis of the frame, and wherein the second ground wire is coupled to and extends between the first ground wire and an outer chassis of the frame.
